(19) United States
(12) Patent Application Publication
(10) Pub. No.: US 2023/0211277 A1
(43) Pub. Date: Jul. 6, 2023

(54) DRY GAS SCRUBBER

(71) Applicant: CSK INC., Yongin-si, Gyeonggi-do (KR)

(72) Inventors: MyungKeun Noh, Yongin-si, Gyeonggi-do (KR); Hyeon Yun Cho, Yongin-si, Gyeonggi-do (KR); SoLim Kang, Yongin-si, Gyeonggi-do (KR); JinHong Kim, Yongin-si, Gyeonggi-do (KR); JaeMyeong Choi, Yongin-si, Gyeonggi-do (KR)

(21) Appl. No.: 18/001,011

(22) PCT Filed: May 26, 2021
(86) PCT No.: PCT/IB2021/054567

§ 371 Date: Dec. 7, 2022

(30) Foreign Application Priority Data
Jun. 11, 2020 (GB) 2008864.7

(51) Int. Cl. B01D 53/04; B01D 53/00; B01F 25/431; B01D 46/24; F23J 15/06; F23J 15/02; B01D 46/00

(52) U.S. Cl. CPC B01D 53/0438; B01D 53/002; B01F 25/43163; B01D 46/24; F23J 15/06; F23J 15/025; B01D 53/0415; B01D 46/0036; B01F 2025/919

(57) ABSTRACT

An apparatus for a dry gas scrubber includes: a cooling chamber defined by a housing having an inlet for receiving an effluent stream for treatment by the dry gas scrubber, an outlet for providing the effluent stream for treatment by the dry gas scrubber, and at least one cooling plate within the chamber, the cooling plate being thermally coupled with the housing and configured to deviate a direction of flow of the effluent stream when flowing from the inlet to the outlet. In this way, the cooling chamber is interposed between the process tool and the resin chamber of the dry gas scrubber and operates to cool the effluent stream prior to its being delivered to the resin chamber. Cooling the effluent stream in this way helps to improve the performance of the resin, even when the effluent stream is at an elevated temperature.

### CROSS-REFERENCE OF RELATED APPLICATION

This application is a Section 371 National Stage Application of International Application No. PCT/IB2021/054567, filed May 26, 2021, and published as WO 2021/250498 A1 on Dec. 16, 2021, the content of which is hereby incorporated by reference in its entirety and which claims priority of British Application No. 2008864.7, filed Jun. 11, 2020.

### FIELD

The field of the invention relates to an apparatus for a dry gas scrubber.

### BACKGROUND

Dry gas scrubbers are known. Dry gas scrubbers are used often in the processing of effluent streams from semiconductor processing tools. The dry gas scrubbers perform dry resin abatement to abate gases that readily adsorb and react with material on the resin. Although such dry scrubbers exist, they each have their own shortcomings. Accordingly, it is desired to provide an improved dry gas scrubber.

The discussion above is merely provided for general background information and is not intended to be used as an aid in determining the scope of the claimed subject matter. The claimed subject matter is not limited to implementations that solve any or all disadvantages noted in the background.

### SUMMARY

According to a first aspect, there is provided an apparatus for a dry gas scrubber, comprising: a cooling chamber defined by a housing having an inlet for receiving an effluent stream for treatment by the dry gas scrubber, an outlet for providing the effluent stream for treatment by the dry gas scrubber, and at least one cooling plate within the chamber, the cooling plate being thermally coupled with the housing and configured to deviate a direction of flow of the effluent stream when flowing from the inlet to the outlet.

The first aspect recognizes that a problem with existing arrangements is that the effluent stream can arrive at the dry gas scrubber at an elevated temperature. That elevated temperature may damage or reduce the effectiveness of the dry gas scrubber. Accordingly, an apparatus is provided. The apparatus may be for a dry gas scrubber. The apparatus may comprise a cooling chamber. The cooling chamber may be defined by a housing or enclosure. The housing may have an inlet. The inlet may receive an effluent stream to be treated by the dry gas scrubber. The housing may have an outlet which provides the effluent stream to be treated by the dry gas scrubber. The housing may have one or more cooling plates positioned within the cooling chamber. The cooling plate may be thermally coupled with the housing. That is to say, the cooling plate may provide a conductive path to the housing. The cooling plate may deviate, change or alter a direction of flow of the effluent stream within the cooling chamber when travelling from the inlet to the outlet. In this way, the cooling chamber is interposed between the process tool and the resin chamber of the dry gas scrubber and operates to cool the effluent stream prior to its being delivered to the resin chamber. Cooling the effluent stream in this way helps to improve the performance of the resin, even when the effluent stream is at an elevated temperature.

The cooling chamber may comprise a plurality of cooling plates. Increasing the number of cooling plates can increase the cooling efficiency of the cooling chamber.

The cooling plates may be positioned along the direction of flow of the effluent stream when flowing from the inlet to the outlet.

The cooling plates may extend at least partially across the chamber to provide an unobstructed portion to facilitate flow from the inlet to the outlet.

Adjacent cooling plates may at least partially extend in opposing directions across the chamber to provide opposing unobstructed portions to deviate the direction of flow from the inlet to the outlet.

The cooling plates may be configured to at least partially provide a serpentine direction of flow from the inlet to the outlet. This helps to increase the dwell time of the effluent stream within the cooling chamber and increase thermal contact with the effluent stream to improve the cooling of the effluent stream.

The housing may be cylindrical and the cooling plates may be at least partially defined by a circular sector.

The housing may comprise an inner conduit which at least partially extends between the inlet and the outlet. Providing an inner conduit helps to further enhance the cooling of the effluent stream.

The inner conduit may be positioned to divide the effluent stream flowing from the inlet to the outlet into a first stream which flows around the cooling plates and into a second stream which flows through the inner conduit.

The cooling plates may extend between the inner conduit and the housing to provide a thermal path between the inner conduit and the housing.

The inner conduit may comprise at least one inlet aperture proximate the inlet and at least one outlet aperture proximate the outlet to facilitate flow of the second stream from the inlet to the outlet.

The at least one aperture may be orientated to facilitate flow of the second stream in a direction away from the outlet.

The at least one aperture may be orientated to facilitate flow of the second stream in a direction transverse to a direction of flow of the first stream. This helps to improve mixing of the first stream and the second stream in order to further enhance overall cooling.

The at least one aperture is positioned to reconverge first the first stream and the second stream into a single stream flowing to the outlet.

The inner conduit may comprise a blind tube having a blind end proximate the outlet, the blind end being thermally coupled with the housing to provide a thermal path between the inner conduit and the housing. This helps to improve the cooling of the effluent stream through improving the thermal conductivity between the inner conduit and the housing.

The at least one aperture may be positioned proximate the blind end.

The cooling chamber may comprise at least one cooling fin thermally coupled with the housing. This helps to improve the cooling of the housing.

The apparatus may comprise a powder trap having at least one filter, the powder trap being located downstream of the cooling chamber.

The powder trap may comprise at least one cooling fin located on its external surface.

The apparatus may comprise a resin chamber, the resin chamber being located downstream of the powder trap.

Further particular and preferred aspects are set out in the accompanying independent and dependent claims. Features of the dependent claims may be combined with features of the independent claims as appropriate, and in combinations other than those explicitly set out in the claims.

Where an apparatus feature is described as being operable to provide a function, it will be appreciated that this includes an apparatus feature which provides that function or which is adapted or configured to provide that function.

The Summary is provided to introduce a selection of concepts in a simplified form that are further described in the Detailed Description. This summary is not intended to identify key features or essential features of the claimed subject matter, nor is it intended to be used as an aid in determining the scope of the claimed subject matter.

### BRIEF DESCRIPTION OF THE DRAWINGS

Embodiments of the present invention will now be described further, with reference to the accompanying drawings, in which:

FIG. 1 illustrates schematically the main components of a gas scrubber according to one embodiment;

FIG. 2 illustrates a cooling module 310 according to one embodiment; and

FIG. 3 illustrates the filter module 320 in more detail.

### DETAILED DESCRIPTION

Before discussing the embodiments in any more detail, first an overview will be provided. Embodiments provide apparatus or components of a dry gas scrubber. One apparatus is a cooling chamber provided within a housing or enclosure which conveys the effluent stream which is to be treated by the dry gas scrubber. The cooling chamber has one or more cooling plates which are thermally coupled with the housing and deviate or alter the direction of flow of the effluent stream flowing through the cooling chamber. This helps to increase the dwell time of the effluent stream as it passes through the cooling chamber, which helps to cool the effluent stream to a temperature more suited to an operating temperature of the resin in the dry gas scrubber. The cooling plates are thermally coupled with the housing to help improve heat conduction from the effluent stream to the ambient atmosphere. The cooling chamber can be provided with a central conduit which extends within the cooling chamber which provides a separate flow path for the effluent stream, effectively splitting the effluent stream into two flows, one passing through the central conduit and the other interacting with the cooling plates. The portion of the effluent stream passing through the central conduit is typically hotter than the remainder of the effluent stream. The central conduit is also thermally coupled with the housing and typically with the cooling plates to facilitate heat transfer from the effluent stream via the inner conduit to the housing which again helps to improve the cooling of the effluent stream as it passes through the cooling chamber. The effluent stream exiting the conduit is typically arranged to intersect the effluent stream flowing past the cooling plates to induce turbulence and increase mixing prior to the effluent stream exiting the cooling chamber. The cooled effluent stream is provided from the cooling chamber to a downstream powder trap which helps to capture powder or particular matter within the cooled effluent stream, filter the cooled effluent stream and further cool the effluent stream through thermal conduction between the effluent stream and the powder trap prior to delivery to the dry gas scrubber. The presence of the powder trap therefore helps to reduce the amount of particulate matter or powder which may impair the efficiency of the resin within the dry gas scrubber as well as helping to further cool the effluent stream prior to delivery to the dry gas scrubber which helps to improve the performance of the resin.

### Dry Gas Scrubber

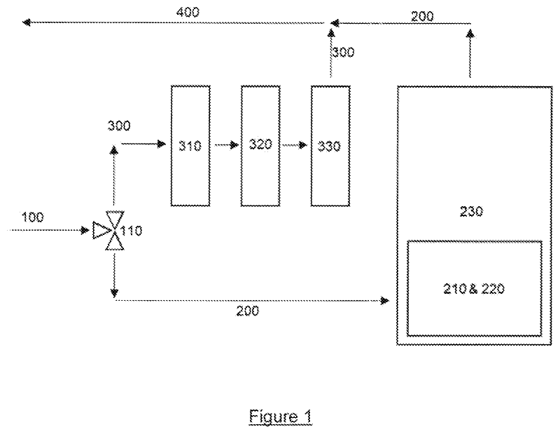

FIG. 1 illustrates schematically the main components of a gas scrubber according to one embodiment. The effluent stream is supplied to an inlet 100 and the supplied effluent stream is divided into a main process flow 200 and a bypass flow 300 under the control of a three-way valve 110. When operated with the main process flow 200, the effluent stream is supplied to a main canister 230. The effluent stream supplied to the main canister 230 is cooled by a cooling unit 210 installed below. The powder produced by the cooling unit 210 is collected by a powder trap 220 and the effluent stream moves to an upper resin chamber. The effluent stream is adsorbed by the resin inside and discharged to an outlet 400. To facilitate servicing of the main canister 230, the three-way valve can by operated to active the by-pass flow 300 where the gas is cooled by a cooling module 310. The powder contained in the cooled gas is then filtered by a filter module 320. Then, it is supplied to an auxiliary canister 330 for the adsorption treatment by the resin therein and discharged through the outlet 400.

### Cooling Module

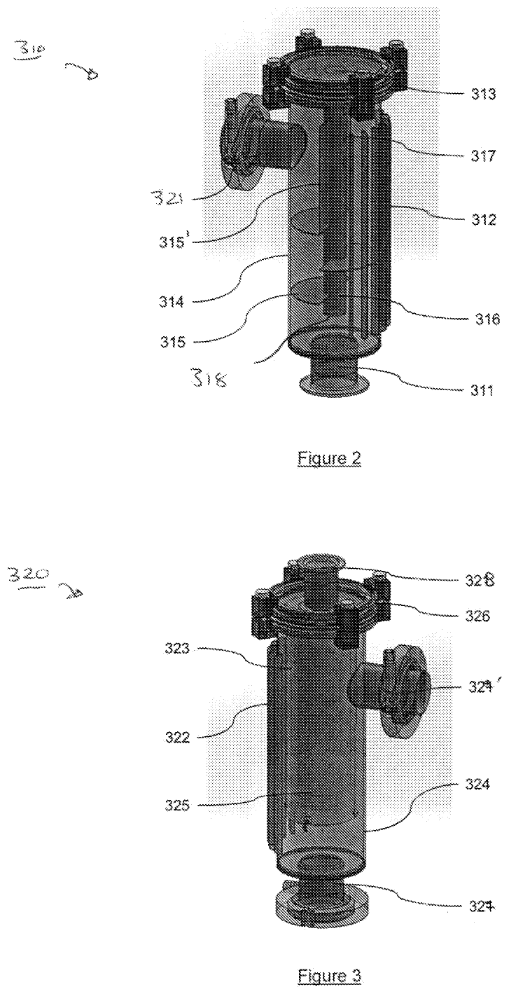

FIG. 2 illustrates a cooling module 310 according to one embodiment. The cooling module 310 has a housing 314, which in this embodiment is cylindrical. However, it will be appreciated that other shaped housings are possible. An inlet 311 and an outlet 321 couple with the housing 314. In this arrangement, the inlet 311 is located on an axial face of the housing 314 and the outlet 321 is located on a circumferential face of the housing 314 proximate the opposing axial face.

Within a cooling chamber defined by the housing 314 is provided a set of cooling plates 315. The cooling plates in this arrangement extend radially and are orientated in a direction which is transverse to the central axis of the housing 314. Also in this arrangement the cooling plates 315 extend across approximately half of the cooling chamber. Also in this arrangement cooling plates are provided at different positions along the axial length of the cooling chamber. Also in this arrangement, adjacent cooling plates 315 extend radially in opposing directions. However, it will be appreciated that other arrangements are possible.

An inner conduit 316 extends axially along a portion of the cooling chamber. In particular, the inner conduit 316 extends from an end plate 313 proximate the outlet 321 and stops short of the inlet 311. The inner conduit has an inlet aperture 318 in fluid communication with the outlet apertures 317. The inlet aperture 318 is coaxially located and proximate to the inlet 311. The inner conduit 316 in this arrangement is also cylindrical. However, it will be appreciated that other shapes are possible. The inner conduit 316 supports the cooling plates 315 which provide a thermal path from the inner conduit 316 to the housing 314. The inner conduit 316 defines a number of apertures 317. The apertures 317 are orientated away from the outlet 321. One of the cooling plates 315′ has a transverse component which extends axially to provide a sub-chamber proximate the outlet 321.

The housing 314 has one or more heat sinks 312 which are positioned circumferentially around the external surface of the housing 314 and extend axially along the housing 314.

In operation, the effluent stream is received at the inlet 311 and passes into the cooling chamber. Some of the effluent stream passes into the inlet aperture 318, travels through the inner conduit 316 and exits through the outlet apertures 317. The remainder of the effluent stream is prevented from flowing axially directly towards the outlet 321 by the presence of the cooling plates 315. Instead, the cooling plates deflect the effluent stream which follows a serpentine flow past the cooling plates until it reconverges with the effluent stream flowing from the outlet apertures 317. The different directions of flow as the effluent stream reconverges causes mixing. The effluent stream then flows through the gap between the transverse portion of the cooling plate 315 and the end plate 313 and flows through the outlet 321.

Splitting the effluent stream into two streams helps to improve cooling. In particular, the typically cooler portion of the effluent stream flowing around the cooling plates 315, 315′ is cooled due to thermal conduction between the effluent stream and the cooling plates 315, 315′ (which are thermally coupled with both the inner conduit 316 and the housing 314) and through thermal conduction between the effluent stream and the housing 314. The presence of the cooling plates 315, 315′ helps to increase the cooling contact with the effluent stream. In addition, the typically hotter portion of the effluent stream flowing through the inner conduit 316 is cooled through thermal contact between the inner conduit 316 and the effluent stream. The inner conduit 316 is cooled due to thermal contact with the end plate 313 and through thermal contact with the cooling plates 315, 315′ (which in turn are thermally coupled with the housing 314). The mixing as the two portions of the effluent stream reconverge also helps to unify the temperature of the effluent stream. The presence of the heat sinks 312 on the housing 314 helps to improve the thermal cooling of the housing 314.

### Filter Module

FIG. 3 illustrates the filter module 320 in more detail. The filter module 320 comprises a housing 324. In this arrangement, the housing 324 is also cylindrical but it will be appreciated that other shaped housings are possible. An inlet 327 is provided in an axial end face of the housing 324. An outlet 328 is provided in the other axial face of the housing 324. An alternate inlet 327′ is provided in the circumferential wall of the housing 324 proximate the outlet 328. This alternate inlet 327′ is sometimes used when different physical configurations of modules are required. Coupled with the outlet 328 is a perforated tube 325. The perforated tube 325 extends axially from the outlet 328 at least partially along the axial length of the housing 324. One or more filters 323 surround and are supported on the perforated tube 325. An annular gap is retained between the outer surface of the filter 323 and the inner surface of the housing 324. Heat sinks 322 are located circumferentially around the outer surface of the housing 324 and extend at least partially along its axial length.

In operation, the effluent stream provided by the outlet 321 is received by the inlet 327. The effluent stream passes into the filter module 320. Powder can gather below the filters 323 in order to help reduce clogging of the filters 323. The effluent stream passes through the filters 323 and the perforated tube 325 and exits via the outlet 328 to the auxiliary canister 330 which contains the resin. The contact between the effluent stream and the housing 324 and between the effluent stream and the perforated tube 325 helps to further cool the effluent stream, with the cooling being enhanced by the presence of the heat sinks 322.

It will be appreciated that the order and quantity of cooling/filtering can be changed according to the process and operating environment. For example, if the purpose is to remove the powder first and then lower the temperature, the filter module 320 can receive the effluent stream first and the cooling module 310 can be placed downstream of the filter module 320.

Hence, some embodiments produce a modular form that allows cooling and powder collection during the bypass flow of the effluent stream. The cooling module is separated into a wall flow and a central flow of the supplied effluent stream. The wall flow is cooled by the outer wall and mixed back with the central flow. Depending on the cooling performance, one or more modules can be installed. Three-way flow can be applied to the module to select the flow direction to suit the environment. Some embodiments provide an energy-saving cooling device using heat exchange with a wall surface by controlling the flow of internal airflow without using a coolant such as cooling water, N2 or CDA in the gas cooling method.

In some embodiments, the cooler module in the bypass flow controlled by the inlet 3-way valve is supplied through the port of the cooler module. The supplied effluent stream is separated into a central flow and a wall flow by the inner tube. The central flow flows through the inner tube, exchanges heat with the wall flow, and is discharged through the inner tube hole. In the discharged portion, the mixture is cooled by mixing with the wall flow and discharged through the opposite port. The wall flow separated by the inner tube flows evenly inside the module body by the baffle and is cooled by the outer wall surface. The central flow discharged from the inner tube hole is mixed with the wall flow and discharged through the opposite port. The baffle is fixed to the inner tube and the inner tube is fixed to the top blind. The cooler module is largely composed of a module body and a top blind. In order to increase the cooling efficiency of the wall flow, a heat sink pin may be installed outside the module body. The effluent stream is cooled through the cooler module and powder contained in the effluent stream is filtered by the filter module. The effluent stream is supplied through the port and moved to the space of the module body and the filter material. The powder is filtered by the filter material and the effluent stream is discharged by the upper port. The effluent stream supply port can be used on the lower side or both sides. The filter material used to filter the particles is installed on the outer surface of the perforated tube. The perforated tube is assembled to and detachable from the top flange to simplify maintenance. The filter module may install a heat sink pin on the module body in order to increase the efficiency of cooling in addition to the filtering purpose of the powder. The effluent stream supplied to the dry gas scrubber is cooled and powder collected by the apparatus described above and then the gas is processed and discharged through the resin.

Although illustrative embodiments of the invention have been disclosed in detail herein, with reference to the accompanying drawings, it is understood that the invention is not limited to the precise embodiment and that various changes and modifications can be effected therein by one skilled in the art without departing from the scope of the invention as defined by the appended claims and their equivalents.

Although elements have been shown or described as separate embodiments above, portions of each embodiment may be combined with all or part of other embodiments described above.

Although the subject matter has been described in language specific to structural features and/or methodological acts, it is to be understood that the subject matter defined in the appended claims is not necessarily limited to the specific features or acts described above. Rather, the specific features and acts described above are described as example forms of implementing the claims.

1. An apparatus for a dry gas scrubber, comprising:
a cooling chamber defined by a housing having
an inlet for receiving an effluent stream for treatment by said dry gas scrubber,
an outlet for providing said effluent stream for treatment by said dry gas scrubber, and
at least one cooling plate within said chamber, said cooling plate being thermally coupled with said housing and configured to deviate a direction of flow of said effluent stream when flowing from said inlet to said outlet.

2. The apparatus of claim 1, comprising a plurality of cooling plates.

3. The apparatus of claim 2, wherein said cooling plates are positioned along said direction of flow of said effluent stream when flowing from said inlet to said outlet.

4. The apparatus of claim 2, wherein said cooling plates at least partially extend across said chamber to provide an unobstructed portion to facilitate flow from said inlet to said outlet.

5. The apparatus of claim 2, wherein adjacent cooling plates at least partially extend in opposing across said chamber to provide opposing unobstructed portions deviate said direction of flow from said inlet to said outlet.

6. The apparatus of claim 2, wherein said cooling plates are configured to at least partially provide a serpentine direction of flow from said inlet to said outlet.

7. The apparatus of claim 1, wherein said housing comprises an inner conduit at least partially extending between said inlet and said outlet.

8. The apparatus of claim 7, wherein said inner conduit is positioned to divide said effluent stream flowing from said inlet to said outlet into a first stream flowing around said cooling plates and a second stream flowing through said inner conduit.

9. The apparatus of claim 7, wherein said cooling plates extend between said inner conduit and said housing to provide a thermal path between said inner conduit and said housing.

10. The apparatus of claim 7, wherein said inner conduit comprises at least one inlet aperture proximate said inlet and at least one outlet aperture proximate said outlet to facilitate flow of said second stream from said inlet to said outlet.

11. The apparatus of claim 10, wherein said at least one outlet aperture is orientated to facilitate flow of said second stream in a direction transverse to a direction of flow of said first stream.

12. The apparatus of claim 10, wherein said at least one outlet aperture is positioned to reconverge said first stream and said second stream into a single stream flowing to said outlet.

13. The apparatus of claim 10, wherein said inner conduit comprises a blind tube having a blind end proximate said outlet, said blind end being thermally coupled with said housing to provide a thermal path between said inner conduit and said housing.

14. The apparatus of claim 1, comprising a powder trap having at least one filter, said powder trap being located downstream of said cooling chamber and preferably wherein said powder trap comprises at least one cooling fin located on its external surface.

15. The apparatus of claim 14, comprising a resin chamber, said resin chamber being located downstream of said powder trap.
